(19) United States
(12) Patent Application Publication
(10) Pub. No.: US 2025/0100085 A1
(43) Pub. Date: Mar. 27, 2025

(54) MACHINING CONDITION ACQUISITION METHOD AND LASER MACHINING DEVICE

(71) Applicant: HAMAMATSU PHOTONICS K.K., Hamamatsu-shi, Shizuoka (JP)

(72) Inventors: Yo SUGIMOTO, Hamamatsu-shi, Shizuoka (JP); Yuta KONDOH, Hamatsu-shi, Shizuoka (JP); Takeshi SAKAMOTO, Hamamatsu-shi, Shizuoka (JP)

(73) Assignee: HAMAMATSU PHOTONICS K.K., Hamamatsu-shi, Shizuoka (JP)

(21) Appl. No.: 18/727,716

(22) PCT Filed: Oct. 31, 2022
(86) PCT No.: PCT/JP2022/040801

§ 371 Date: Jul. 10, 2024

(30) Foreign Application Priority Data
Jan. 26, 2022 (JP) 2022-010002

(51) Int. Cl. B23K 26/53; B23K 26/03; B23K 26/04; B23K 26/38; B23K 101/40

(52) U.S. Cl. CPC B23K 26/53; B23K 26/032; B23K 26/048; B23K 26/38; B23K 2101/40

(57) ABSTRACT

There is provided a processing condition acquisition method for acquiring conditions of laser processing for forming a weakened region in a functional element layer by irradiating an object with laser light from a first surface side, the object including a substrate including a first surface and a second surface opposite to the first surface, and the functional element layer provided on the second surface of the substrate, the method including: a first step of performing first processing as the laser processing a plurality of times at different positions in the first surface while changing a converging position of the laser light in a Z direction intersecting the first surface within a range including an interface between the substrate and the functional element layer.

### TECHNICAL FIELD

The present disclosure relates to a processing condition acquisition method and a laser processing device.

### BACKGROUND ART

Patent Literature 1 describes a method for forming a weakened region along a planned cutting line in a metal film, which is formed on a back surface side of a workpiece, by irradiating a front surface of the workpiece as an incident surface for laser light with the laser light. At this time, the converging point of the laser light is positioned outside a silicon wafer that is a workpiece.

### CITATION LIST

### Patent Literature

Patent Literature 1: Japanese Patent No. 5322418

### SUMMARY OF INVENTION

### Technical Problem

According to the method described in Patent Literature 1, by forming a weakened region having a predetermined depth in a metal film along a planned cutting line, the workpiece can be accurately cut along the planned cutting line with a relatively small external force. Particularly, in recent years, in order to cope with the miniaturization of wirings of a device, due to the adoption of a low-k film as an insulating film, an increase in the number of stacked patterns associated with three-dimensionalization, or the like, a plurality of films, metal wirings, or metal films may be stacked, and it is more effective to form the weakened region in a cutting region as described above. Accordingly, a method for acquiring processing conditions suitable for forming a weakened region is desired.

Therefore, an object of the present disclosure is to provide a processing condition acquisition method and a laser processing device capable of acquiring processing conditions suitable for forming a weakened region.

### Solution to Problem

A processing condition acquisition method according to the present disclosure is a processing condition acquisition method for acquiring conditions of laser processing for forming a weakened region in a functional element layer by irradiating an object with laser light from a first surface side, the object including a substrate including the first surface and a second surface opposite to the first surface, and the functional element layer provided on the second surface of the substrate, the method including: a first step of performing first processing as the laser processing a plurality of times at different positions in the first surface while changing a converging position of the laser light in a Z direction intersecting the first surface within a range including an interface between the substrate and the functional element layer; a second step of acquiring an interface image by capturing an image of the interface between the substrate and the functional element layer from the first surface side at each of the positions in the first surface in which the first processing is performed in plurality of times using transmissive light transmitting through the substrate; and a third step of acquiring a range of the converging position of the first processing in the Z direction, in which the interface image including damage caused by the laser light is acquired among a plurality of the interface images acquired in the second step, as one condition of the laser processing.

In this method, the conditions of the laser processing for forming the weakened region in the functional element layer on a second surface side of the object are acquired by performing irradiation with the laser light from the first surface side of the substrate of the object. For that purpose, the laser processing is performed a plurality of times while changing the converging position of the laser light in the Z direction within a range including the interface between the substrate and the functional element layer. In addition, the interface image is acquired by capturing an image of the interface between the substrate and the functional element layer at each of the positions where the laser processing is performed a plurality of times. In the interface image, depending on the converging position, an image of damage caused by the laser light may or may not appear. Further, when the converging position of the laser light is within a range where an image of damage appears in the interface image, the weakened region that allows the object to be cut with good quality tends to be suitably formed. Therefore, in this method, the range of the converging position of the laser processing in which the interface image including an image of damage caused by the laser light is acquired among the plurality of interface images is acquired as one condition of the laser processing. In such a manner, according to this method, the processing condition (the range of the converging position) suitable for forming the weakened region can be acquired.

In the processing condition acquisition method according to the present disclosure, a position range in the Z direction in which the converging position is changed in the first step may include a first range located closer to the first surface side than to the interface, and a second range located closer to a side opposite to the first surface than to the interface, and wider than the first range. Here, the range of the converging position in which the weakened region is suitably formed is more easily obtained on a functional element layer side than at the interface between the substrate and the functional element layer. Therefore, the range where the converging position is changed is made wider on the functional element layer side than at the interface, so that the range can be quickly and reliably acquired.

The processing condition acquisition method according to the present disclosure may further include a fourth step of cutting the object and capturing an image of a front surface of the functional element layer of the cut object after the first step, the second step, and the third step. In the first step, irradiation may be performed with the laser light along an X direction along the first surface, and in the fourth step, the object may be cut along the X direction. In such a manner, by actually cutting the object and capturing an image of the front surface of the functional element layer, a more suitable converging position can be determined through the evaluation of cutting quality.

The processing condition acquisition method according to the present disclosure may further include a fifth step of performing second processing as the laser processing a plurality of times at different positions in the first surface while changing a burst number of the laser light that is pulsed light; a sixth step of acquiring a first surface image by capturing an image of the first surface at each of the positions in the first surface in which the second processing is performed in a plurality of times; and a seventh step of acquiring the burst number of the second processing, at which the first surface image in which no damage occurs to the first surface is acquired among a plurality of the first surface images acquired in the sixth step, as another condition of the laser processing. In this case, a suitable processing condition (burst number) which allows the weakened region to be formed such that no damage occurs to the first surface that is an incident surface for the laser light can be acquired.

A laser processing device according to the present disclosure is a laser processing device that acquires conditions of laser processing for forming a weakened region in a functional element layer by irradiating an object with laser light from a first surface side, the object including a substrate including a first surface and a second surface opposite to the first surface, and the functional element layer provided on the second surface of the substrate, the device including: a support unit that supports the object; a laser irradiation unit that irradiates the object supported by the support unit with the laser light from the first surface side; an imaging unit that captures an image of the object supported by the support unit from the first surface side using transmissive light transmitting through the substrate; and a control unit that controls the laser irradiation unit and the imaging unit. The control unit executes a first process of controlling the laser irradiation unit to perform first processing as the laser processing a plurality of times at different positions in the first surface while changing a converging position of the laser light in a Z direction intersecting the first surface within a range including an interface between the substrate and the functional element layer; a second process of controlling the imaging unit to capture an image of the interface between the substrate and the functional element layer from the first surface side at each of the different positions in the first surface using the transmissive light, thereby acquiring an interface image, the first processing being performed at the positions a plurality of times; and a third process of recording each of a plurality of the interface images acquired in the second process, in association with each of the corresponding converging position of the first processing.

In this device, the conditions of the laser processing for forming the weakened region in the functional element layer on a second surface side of the object are acquired by performing irradiation with the laser light from the first surface side of the substrate of the object. For that purpose, the laser processing is performed a plurality of times while changing the converging position of the laser light in the Z direction within a range including the interface between the substrate and the functional element layer. In addition, the interface image is acquired by capturing an image of the interface between the substrate and the functional element layer at each of the positions where the laser processing is performed a plurality of times. As described above, depending on the converging position, an image of damage caused by the laser light may or may not appear in the interface image. Further, when the converging position of the laser light is within a range where an image of damage appears in the interface image, the weakened region that allows the object to be cut with good quality tends to be suitably formed. Therefore, in this device, each of the plurality of interface images is recorded in association with each corresponding converging position of the laser processing. Accordingly, by referring to the record, the range of the converging position in which the interface image including an image of damage caused by the laser light is acquired among the plurality of interface images can be acquired as one condition of the laser processing. In such a manner, according to this device, the processing condition (the range of the converging position) suitable for forming the weakened region can be acquired.

The laser processing device according to the present disclosure may further include a display unit that displays the image captured by the imaging unit. The control unit may execute a fourth process of controlling the display unit to display each of the interface images recorded in the third process on the display unit. In this case, the range of the converging position of the laser processing in which the interface image including an image of damage caused by the laser light is acquired among the plurality of interface images can be easily identified based on the interface images displayed on the display unit.

### Advantageous Effects of Invention

According to the present disclosure, it is possible to provide the processing condition acquisition method and the laser processing device capable of acquiring processing conditions suitable for forming the weakened region.

### BRIEF DESCRIPTION OF DRAWINGS

FIG. 1 is a schematic view illustrating a schematic configuration of a laser processing device according to the present embodiment.

FIG. 2 is a schematic cross-sectional view for describing laser processing performed by the laser processing device illustrated in FIG. 1.

FIG. 3 is a flowchart illustrating one example of a processing condition acquisition method performed by the laser processing device illustrated in FIG. 1.

FIG. 4 is a schematic cross-sectional view illustrating one step of the processing condition acquisition method illustrated in FIG. 3.

FIG. 5 is a schematic cross-sectional view illustrating one step of the processing condition acquisition method illustrated in FIG. 3.

FIG. 6 is a graph for describing a change in burst number.

FIG. 7 is a view illustrating a plurality of first surface images.

FIG. 8 is a schematic cross-sectional view illustrating one step of the processing condition acquisition method illustrated in FIG. 3.

FIG. 9 is a view illustrating a plurality of interface images.

FIG. 10 is a schematic view illustrating a schematic configuration of a head unit according to a modification example.

### DESCRIPTION OF EMBODIMENTS

Hereinafter, one embodiment will be described with reference to the drawings. Incidentally, in the description of each drawing, the same or corresponding elements are denoted by the same reference signs, and duplicate descriptions may be omitted. In addition, in each drawing, an orthogonal coordinate system defined by an X-axis, a Y-axis, and a Z-axis may be illustrated. A Z direction of the coordinate system is, as one example, a vertical direction. In addition, an X direction and a Y direction are, for example, two horizontal directions intersecting (orthogonal to) each other.

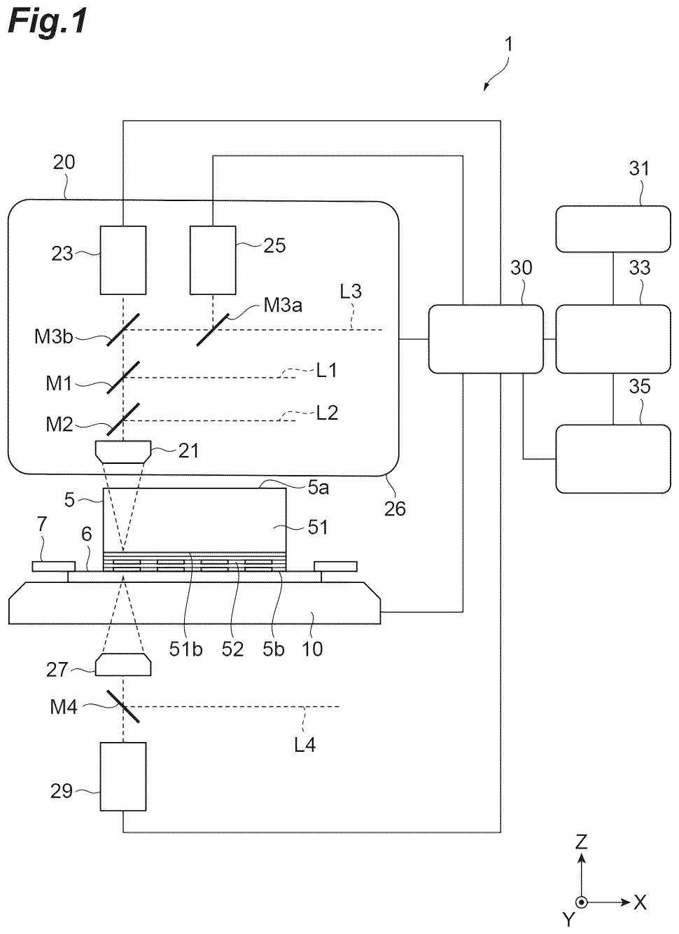

FIG. 1 is a schematic view illustrating a schematic configuration of a laser processing device according to the present embodiment. As illustrated in FIG. 1, a laser processing device 1 includes a table (support unit) 10, a head unit 20, a control unit 30, an input unit 31, a display unit 33, and a recording unit 35. The table 10 is, for example, a transparent table that is transmissive to at least visible light and near-infrared light, and supports an object 5. The object 5 includes a first surface 5a and a second surface 5b opposite to the first surface 5a. The object 5 is supported on the table 10 via a tape 6 provided on the second surface 5b. The tape 6 is held by a frame portion 7, and is, for example, a transparent tape that is transmissive to at least visible light and near-infrared light.

The table 10 may be provided with a first movement mechanism (not illustrated) for moving the table 10 in at least one of the X direction, the Y direction, and the Z direction. Accordingly, the control unit 30 can control the first movement mechanism to drive the table 10 in at least one of the X direction, the Y direction, and the Z direction.

The object 5 includes a substrate 51 and a functional element layer 52. The substrate 51 includes the first surface 5a and a second surface 51b opposite to the first surface 5a. The functional element layer 52 is provided on the second surface 51b. Here, the second surface 5b of the object 5 is a surface on an opposite side of the functional element layer 52 from the substrate 51. The substrate 51 is, for example, a semiconductor substrate containing silicon or the like. The functional element layer 52 is a layer including a plurality of functional elements (semiconductor elements) arranged in the X direction and the Y direction. In the functional element layer 52, a plurality of functional elements may be stacked along the Z direction. In addition, the functional element layer 52 may include a metal wiring, a metal film, or an insulating film such as a low-k film.

The head unit 20 includes a first focusing unit 21, a first camera 23, a second camera 25, and a housing 26. The first focusing unit 21, the first camera 23, and the second camera 25 are accommodated in the housing 26. The first focusing unit 21 includes a lens, receives laser light L1 for processing incident thereon via mirrors M1 and M2, the laser light L1 being emitted from a light source outside the housing 26 and being introduced into the housing 26, and focuses the laser light L1 toward the object 5. Therefore, the head unit 20 is a laser irradiation unit that irradiates the object 5 with the laser light L1 from a first surface 5a side, the object 5 being supported on the table 10. The laser light L1 is transmissive through the substrate 51 of the object 5. As one example, a wavelength of the laser light L1 is approximately 1064 nm, and a pulse width is approximately 9 ps.

In addition, the first focusing unit 21 receives a first observation light L2 incident thereon via the mirror M2, the first observation light L2 being emitted from a light source outside the housing 26 and being introduced into the housing 26, and focuses the first observation light L2 toward the object 5. The first camera 23 receives reflected light of the first observation light L2 incident thereon via mirrors M2, M1, and M3b, the object 5 being irradiated with the first observation light L2, and captures an image of the first observation light L2. The first observation light L2 is, for example, visible light. In this case, the first camera 23 is sensitive to visible light and near-infrared light. Accordingly, the head unit 20 is a first imaging unit that captures an image of the object 5 from the first surface 5a side using the first observation light L2 (acquires an image of the first surface 5a), the object 5 being supported on the table 10.

Further, the first focusing unit 21 receives transmissive light L3 incident thereon via mirrors M3a, M3b, M1, and M2, the transmissive light L3 being emitted from a light source outside the housing 26 and being introduced into the housing 26, and focuses the transmissive light L3 toward the object 5. The second camera 25 receives reflected light of the transmissive light L3 incident thereon via the mirrors M2, M1, M3b, and M3a, the object 5 being irradiated with the transmissive light L3, and captures an image of the transmissive light L3. The transmissive light L3 is, for example, near-infrared light, and is transmissive through the substrate 51 of the object 5. In this case, the second camera 25 is sensitive to near-infrared light. The second camera 25 may be configured as, for example, an InGaAs camera. In such a manner, the head unit 20 is also a second imaging unit (imaging unit) that captures an image of the object 5 from the first surface 5a side using the transmissive light L3 that transmits through the substrate 51, the object 5 being supported on the table 10. The head unit 20 is configured to coaxially irradiate the object 5 with the laser light L1, the first observation light L2, and the transmissive light L3. Incidentally, the above example is an example in which the laser processing device 1 includes the light sources of the laser light L1, the first observation light L2, and the transmissive light L3 outside the head unit 20; however, the laser processing device 1 may include at least one of the light sources inside the head unit 20. In addition, the head unit 20 may be provided with a second movement mechanism (not illustrated) for moving the head unit 20 in at least one of the X direction, the Y direction, and the Z direction. Accordingly, the control unit 30 can control the second movement mechanism to drive the head unit 20 in at least one of the X direction, the Y direction, and the Z direction. A movement direction of the table 10 and a movement direction of the head unit 20 can be set such that the object 5 can be moved in any of the X direction, the Y direction, and the Z direction relative to irradiation positions of the laser light L1, the first observation light L2, and the transmissive light L3 at least by combining the movement directions.

Here, the laser processing device 1 includes a second focusing unit 27 and a third camera 29. The second focusing unit 27 and the third camera 29 are disposed on a side opposite to the head unit 20 with respect to the table 10. The second focusing unit 27 includes a lens, receives a second observation light L4 incident thereon via a mirror M4, the second observation light L4 being emitted from a predetermined light source, and focuses the second observation light L4 toward the object 5. The third camera 29 receives reflected light of the second observation light L4 incident thereon via the mirror M4, the object 5 being irradiated with the second observation light L4, and captures an image of the second observation light L4. The second observation light L4 is, for example, visible light. In this case, the third camera 29 is sensitive to visible light and near-infrared light. Accordingly, the second focusing unit 27 and the third camera 29 constitute a third imaging unit that captures an image of the object 5 from a second surface 5b side (front surface of the functional element layer 52) using the second observation light L4 (acquires an image of the second surface 5b that is the front surface of the functional element layer 52), the object 5 being supported on the table 10.

The control unit 30 is configured as a computer device including a processor, a memory, a storage, a communication device, and the like. In the control unit 30, the processor executes software (program) read into the memory or the like, and controls reading and writing of data in the memory and the storage and communication by the communication device. The control unit 30 controls operation of each part of the laser processing device 1. A specific operation of the control unit 30 will be described later.

The input unit 31 receives an input from a user, and outputs the input to the control unit 30. The display unit 33 displays various types of information such as information input to and received by the input unit 31, information output from the control unit 30, or information recorded in the recording unit 35. The input unit 31 and the display unit 33 may be integrated and configured as a graphical user interface (GUI). The recording unit 35 records various types of information.

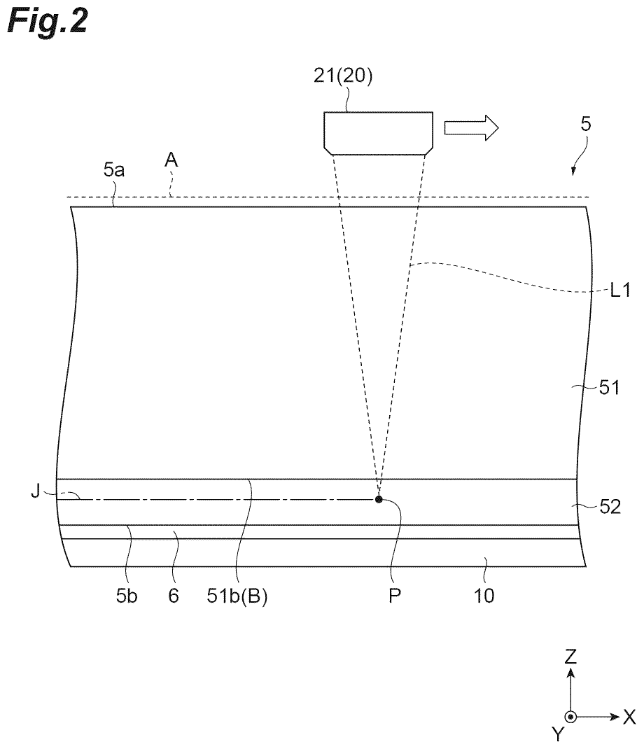

In the laser processing device 1 as described above, laser processing for forming a weakened region J in the functional element layer 52 can be performed by irradiating the object 5 with the laser light L1. FIG. 2 is a schematic cross-sectional view for describing the laser processing performed by the laser processing device illustrated in FIG. 1. As illustrated in FIG. 2, in the laser processing device 1, the object 5 supported on the table 10 such that the first surface 5a faces a head unit 20 side is irradiated with the laser light L1 from the first surface 5a side. At this time, a converging point P (converging position) of the laser light L1 is positioned in the vicinity of an interface B between the substrate 51 and the functional element layer 52 (inside the functional element layer 52 in the illustrated example) in the Z direction.

Namely, the laser light L1 transmits through the substrate 51, is focused at the converging position, and is used to machine the object 5 at the converging position. In this state, the converging point P of the laser light L1 is moved relative to the object 5 along the X direction by driving the table 10 and/or the head unit 20 along the X direction. Accordingly, the object 5 is irradiated with the laser light L1 along a line A along the X direction. As a result, the weakened region J is formed in the functional element layer 52 along the line A.

The weakened region J is a region where the functional element layer 52 is weakened. Weakening includes embrittlement. The weakening of the functional element layer 52 refers to thermal damage such as melting and evaporation due to absorption of the laser light L1 in at least a partial region of the functional element layer 52 (for example, a portion of the functional element layer 52, at least one of a plurality of layers constituting the functional element layer 52, and the like), a change in chemical bond due to laser irradiation, a result of non-thermal processing such as cutting or ablation processing, and the like. The weakening of the functional element layer 52 means that, as a result, when stress such as bending stress or tensile stress is applied to the functional element layer 52, cutting or breakage is more likely to occur in the weakened region compared to a non-treated region (region that is not weakened). The weakened region (embrittled region) J can also be said to be a region where a trace caused by laser irradiation has occurred, and is a region where cutting or breakage is more likely to occur compared to the non-treated region. Incidentally, the weakened region J may be continuously formed in a line shape in at least a partial region of the functional element layer 52, or may be intermittently formed according to a pulse pitch of laser irradiation.

Namely, when a plurality of weakened spots are arranged by performing irradiation with laser light, which is pulsed light, to form the weakened region J, one weakened spot being formed by performing irradiation with one pulse of laser light, the adjacent weakened spots may be continuously connected to each other, may be intermittently connected to each other, or may be separated and independent of each other. In addition, the weakened spots may be exposed on the front surface (second surface 5b) of the functional element layer 52, and the exposed weakened spots may be continuously connected to each other, may be intermittently connected to each other, or may be separated and independent of each other.

Incidentally, the line A is set along the X direction to pass through a street region between the functional elements included in the functional element layer 52 (in practice, a plurality of the lines A can be set in a grid pattern along the X direction and the Y direction). The line A is a planned cutting line for cutting the object 5 for each functional element. Therefore, by forming the weakened region J in the functional element layer 52 (street region) along the line A as described above, the object 5 can be accurately cut along the line A with a relatively small external force.

Here, in recent years, in order to cope with the miniaturization of wirings of a device, due to the adoption of a low-k film as an insulating film, an increase in the number of stacked patterns associated with three-dimensionalization, or the like, a plurality of films, metal wirings, or metal films may be stacked, and it is more effective to form the weakened region J as described above. Accordingly, a method for acquiring processing conditions suitable for forming the weakened region J is desired. Therefore, in the laser processing device 1, suitable processing conditions of the laser processing for forming the weakened region J are acquired. Hereinafter, the acquisition of the processing conditions will be described.

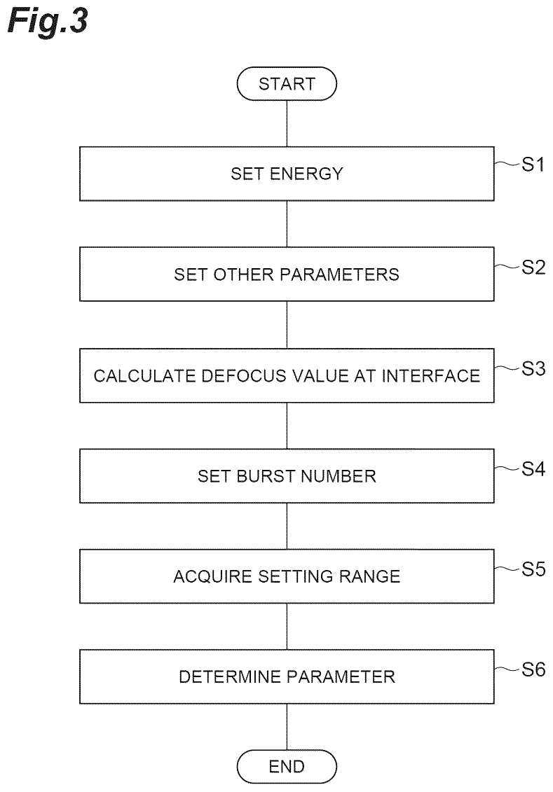

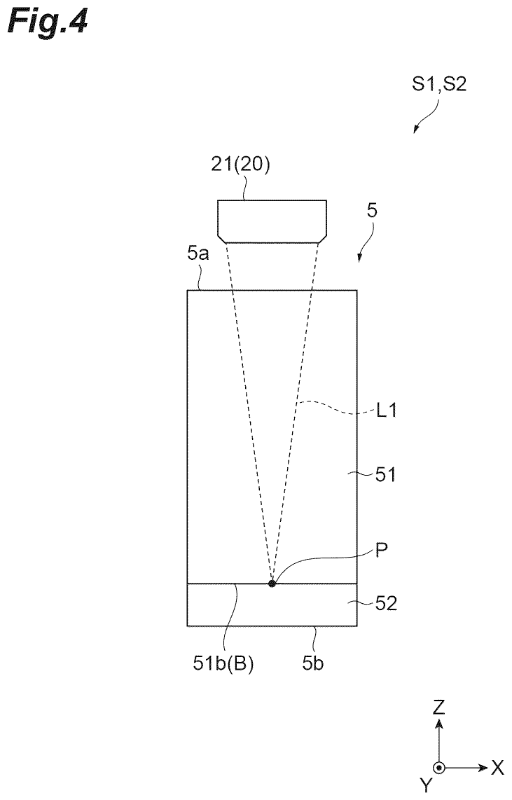

FIG. 3 is a flowchart illustrating one example of a processing condition acquisition method performed by the laser processing device illustrated in FIG. 1. As illustrated in FIG. 3, first, energy of the laser light L1 emitted from the first focusing unit 21 (objective lens) is set (step S1). As illustrated in FIG. 4, the laser light L1 emitted from the first focusing unit 21 is attenuated by reflection on the first surface 5a, which is an incident surface of the object 5 for the laser light L1, and absorption by the substrate 51 until the laser light L1 reaches the interface B between the substrate 51 and the functional element layer 52. Therefore, an energy E of the laser light L1 emitted from the first focusing unit 21 is calculated with respect to an energy e of the laser light L1 at the interface B required to form the weakened regions J in the functional element layer 52, using the calculation formula “e=E×(1−reflectance)×transmittance”.

The “reflectance” indicates a reflectance of the first surface 5a to the laser light L1, and is, as one example, 31.9%. The transmittance is a transmittance of the laser light L1 through the substrate 51, and is calculated based on the relational expression “the amount of transmissive light=the amount of incident light×exp (−αt)” between an absorption coefficient α of the substrate 51 and a thickness t of the substrate 51. The transmittance is, as one example, 41.0%. Therefore, when the energy e is 45 μJ, the above calculation formula becomes 45 μJ=E×(1−0.319)×(0.41), and the energy E is calculated to be approximately 160 μJ. In step S1, the setting of the energy E of the laser light L emitted from the first focusing unit 21 can be performed in the light source by inputting the value calculated in such a manner via the input unit 31. However, in step S1, the control unit 30 may automatically calculate and set the energy E based on various conditions such as the thickness or structure of the object 5 and the mode of the laser processing.

Subsequently, as illustrated in FIG. 3, other parameters are set (step S2). Here, a pulse pitch and a pass number of the laser light L1 are set. The pass number is the number of times (the number of scans) that one line A is irradiated with the laser light L1 while changing the converging position in the Z direction (while maintaining the converging position in the Z direction). Here, as one example, the pulse pitch can be set to approximately 0.5 μm, and the pass number can be set to 1 pass. In step S2, the setting of the parameters can be performed in the light source by receiving an input of the parameters via the input unit 31. However, in step S2 as well, the control unit 30 may automatically select and set the parameters based on various conditions such as the thickness or structure of the object 5 and the mode of the laser processing.

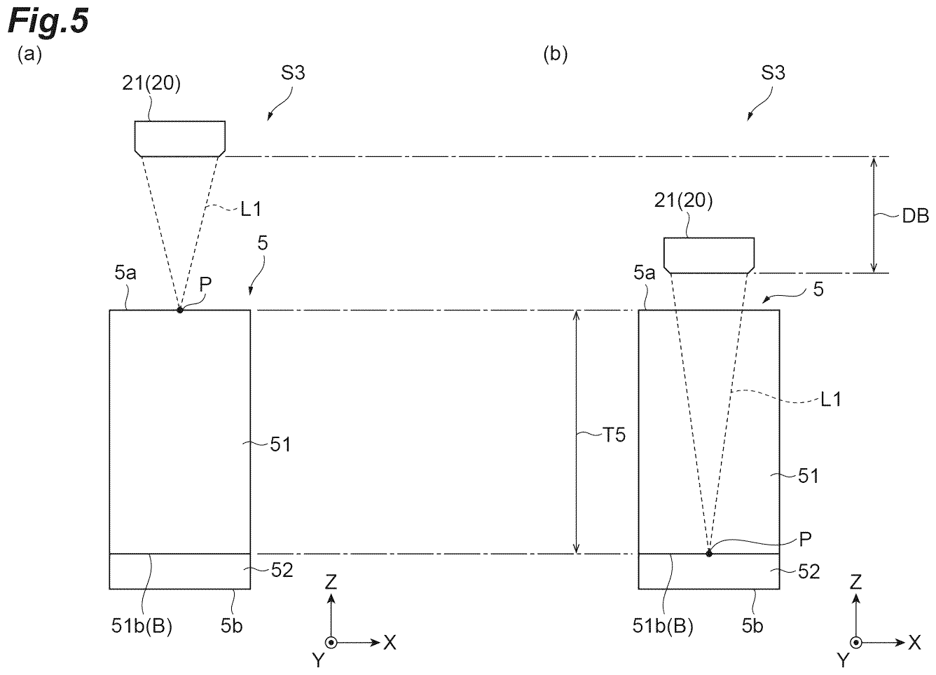

Subsequently, a defocus value when the converging position of the laser light L in the Z direction is at the interface B is calculated (step S3). In step S3, as illustrated in (a) of FIG. 5, a defocus value DB is the amount of relative movement of the first focusing unit 21 (head unit 20) for setting the converging position of the laser light L at the interface B from a state where the converging position (converging point P) of the laser light L is aligned with the first surface 5a, and is calculated based on a thickness T5 of the substrate 51 and a coefficient based on a refractive index of the substrate 51 and the like. The coefficient is the ratio of the amount of movement of the converging point P inside the substrate 51 to the amount of movement of the converging point P outside the substrate 51, and is approximately 4.11 in the case of this experimental system in which the substrate 51 is silicon. The thickness T5 of the substrate 51 is, for example, approximately 730 μm. Accordingly, the defocus value DB is calculated to be, as one example, approximately 178 μm by dividing the thickness T5 by the coefficient. In step S3, the setting of the value calculated in such a manner can be performed by inputting the value via the input unit 31. However, in step S3 as well, the control unit 30 may automatically calculate and set the defocus value DB based on various conditions such as the thickness or structure of the object 5 and the mode of the laser processing.

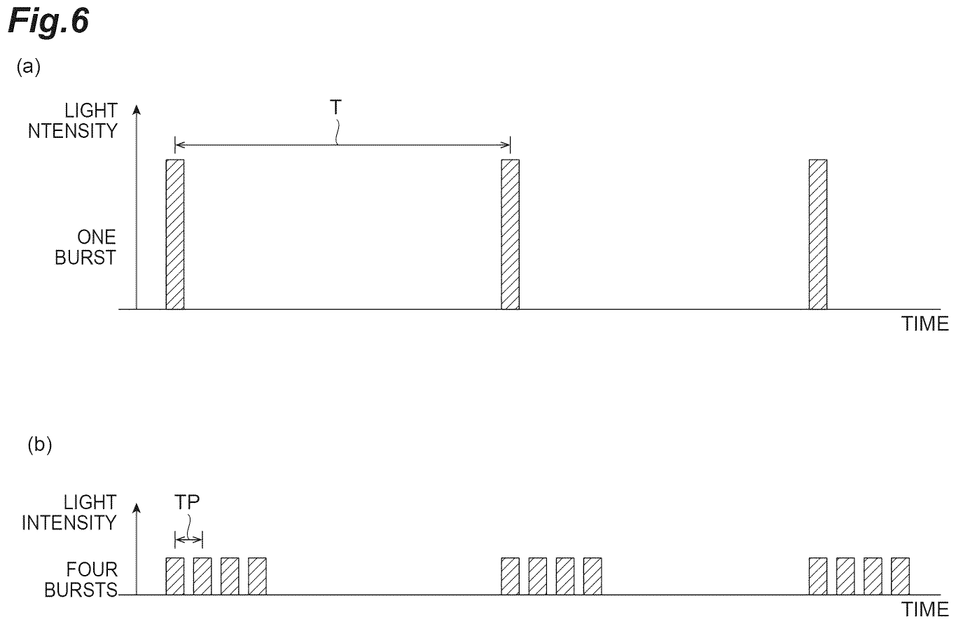

Subsequently, a burst number of the laser light L1 is set (step S4: a fifth step, a sixth step, and a seventh step). More specifically, the laser light L1 is a pulsed light as illustrated in FIG. 6, and the number of bursts (burst number) constituting each pulse can be set. (a) in FIG. 6 illustrates the case of one burst where the burst number is 1 (namely, no burst), and (b) in FIG. 6 illustrates the case of four bursts where the burst number is 4. All the pulse pitches are the same value (for example, 0.5 μm) set in step S2, a period T (frequency interval) is approximately 5 μs, and a burst interval TP is, for example, 25 ns in the case of four bursts. Incidentally, the example of each numerical value is an example in which a repetition frequency is 200 kHz.

A light intensity in the case of four bursts is reduced to approximately ¼ of a light intensity in the case of one burst. Therefore, when the burst number is changed, the presence or absence of damage to the first surface 5a that is the incident surface for the laser light L1 changes. For this reason, in step S4, the burst number is set such that no damage occurs to the first surface 5a.

For that purpose, in step S4, first, the control unit 30 controls the first movement mechanism and/or the second movement mechanism and the laser irradiation unit to irradiate the object 5 with the laser light L1 a plurality of times at different positions in the first surface 5a while setting the converging position of the laser light L1 in the Z direction to a predetermined position and changing the burst number of the laser light L, thereby performing laser processing (second processing) (fifth step). At this time, the converging position of the laser light L1 in the Z direction can be set to the position of the interface B, for example, by using the defocus value DB set in step S3. In addition, the specific numerical value of the burst number of each second processing can be set to, for example, a value input via the input unit 31.

In addition, in each second processing, irradiation can be performed with the laser light L1 along one line A for one burst number. Namely, in step S4, after irradiation is performed with the laser light L1 along one line A for one burst number, the converging position of the laser light L1 can be moved in the Y direction to be positioned on another line A, and irradiation can be performed with the laser light L1 along the other line A for another burst number. In this case, the different positions in the first surface 5a refer to different positions in the Y direction.

Consecutively, in step S4, the control unit 30 controls the first movement mechanism and/or the second movement mechanism and the first imaging unit to capture an image of the first surface 5a at each of the positions in the first surface 5a, thereby acquiring a first surface image, the second processing being performed at the positions a plurality of times (sixth step). Here, for example, a plurality of the first surface images can be acquired by capturing images of the first surface 5a for one line A using the first observation light L2 and the first camera 23, and then moving the head unit 20 relatively to another line A, and capturing images of the first surface 5a for the other line A using the first observation light L2 and the first camera 23.

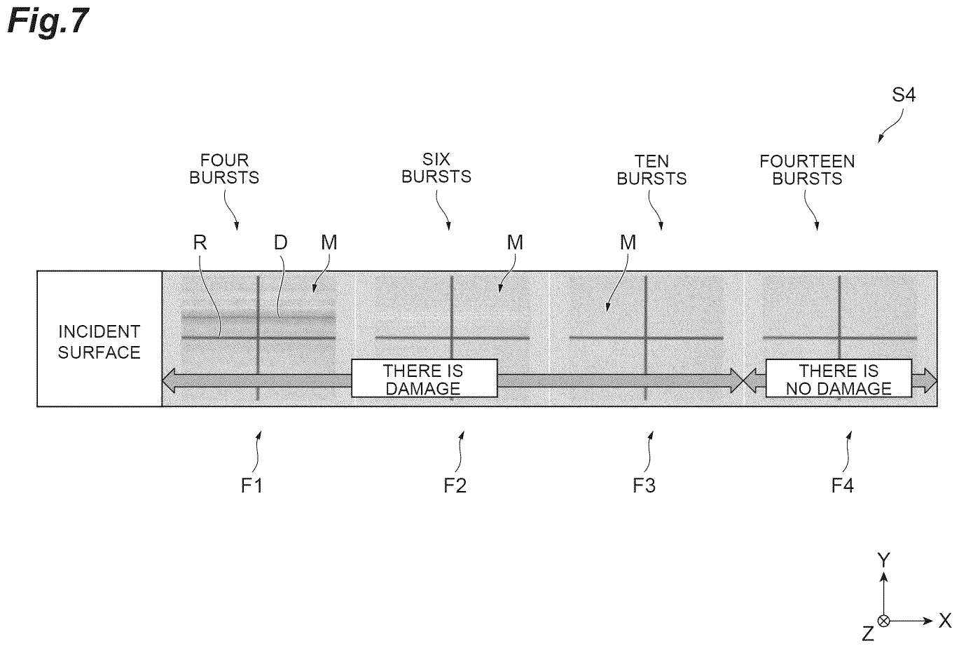

FIG. 7 is a view illustrating a plurality of the first surface images. As illustrated in FIG. 7, in the case of four bursts where the burst number of the laser light L1 is 4, in the case of six bursts where the burst number is 6, and in the case of ten bursts where the burst number is 10, damage D occurs to the first surface 5a, and an image M of the damage D extending along the X direction is included in first surface images F1 to F3. In contrast, in the case of fourteen bursts where the burst number is 14, the damage D does occur to the first surface n5a, and the image M of the damage D is not included in a first surface image F4. Incidentally, in each of the first surface images F1 to F4 in FIG. 7, an image R of a reticle is illustrated.

In such a manner, in step S4, the control unit 30 can associate the plurality of acquired first surface images with the burst numbers corresponding to the first surface images, and can cause the display unit 33 to display the first surface images and the burst numbers side by side. Concurrently, in step S4, the control unit 30 acquires the burst number (the smallest number among the burst numbers, and 14 in this example) of the second processing, at which the first surface images in which no damage occurs to the first surface 5a are acquired among the plurality of acquired first surface images, as a condition of the laser processing (seventh step). Here, the control unit 30 may automatically acquire the burst number of the second processing corresponding to the first surface image that does not include the image M of damage through image processing of the first surface images or the like, or may receive and acquire an input of the burst number for which it is determined that no damage occurs to the first surface 5a, based on the plurality of first surface images displayed on the display unit 33.

Then, in step S4, the burst number during actual processing is set based on the acquired burst number (for example, 14). Here, the acquired burst number itself may be set, or a burst number (for example, 16) obtained by adding a predetermined margin to the acquired burst number may be set.

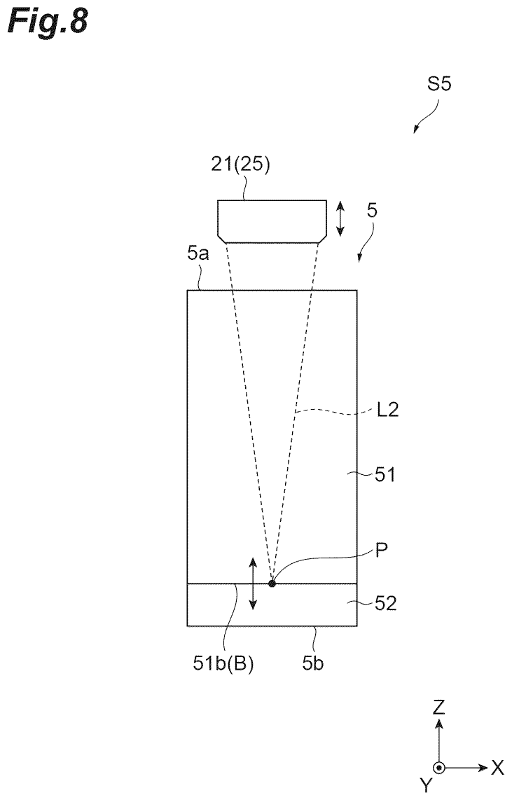

In the subsequent step, the setting range of the converging position of the laser light L1 in the Z direction is acquired (step S5). More specifically, in step S5, as illustrated in FIG. 8, the control unit 30 controls the first movement mechanism and/or the second movement mechanism and the laser irradiation unit to perform laser processing (first processing) a plurality of times at different positions in the first surface 5a while changing the converging position (converging point P) of the laser light L1 in the Z direction within a range including the interface B (first step, first process).

Here, for example, after irradiation is performed with the laser light L1 along one line A at one converging position, the converging position of the laser light L1 can be moved in the Y direction to be positioned on another line A, and irradiation can be performed with the laser light L1 along the other line A at another converging position. In this case, the different positions in the first surface 5a refer to different positions in the Y direction.

In addition, changing the converging position within a range including the interface B refers to changing the defocus value around the defocus value DB, since the defocus value DB at which the converging position is at the interface B is acquired as described above. As one example, the defocus value DB is 178 μm, and the first processing can be performed while changing the defocus value from 174 μm to 202 μm at a pitch of 2 μm. Specific numerical values such as a start value and an end value or a pitch of the defocus values can be acquired, for example, by receiving an input via the input unit 31.

Consecutively, in step S5, the control unit 30 controls the first movement mechanism and/or the second movement mechanism and the second imaging unit to capture an image of the interface B from the first surface 5a side at each of the positions in the first surface 5a using the transmissive light L3 transmitting through the substrate 51, thereby acquiring an interface image, the first processing being performed at the positions a plurality of times (second step, second process). Here, for example, a plurality of the interface images can be acquired by capturing images of the interface B for one line A using the transmissive light L3 and the second camera 25, and then moving the head unit 20 relatively to another line A, and capturing images of the interface B for the other line A using the transmissive light L3 and the second camera 25.

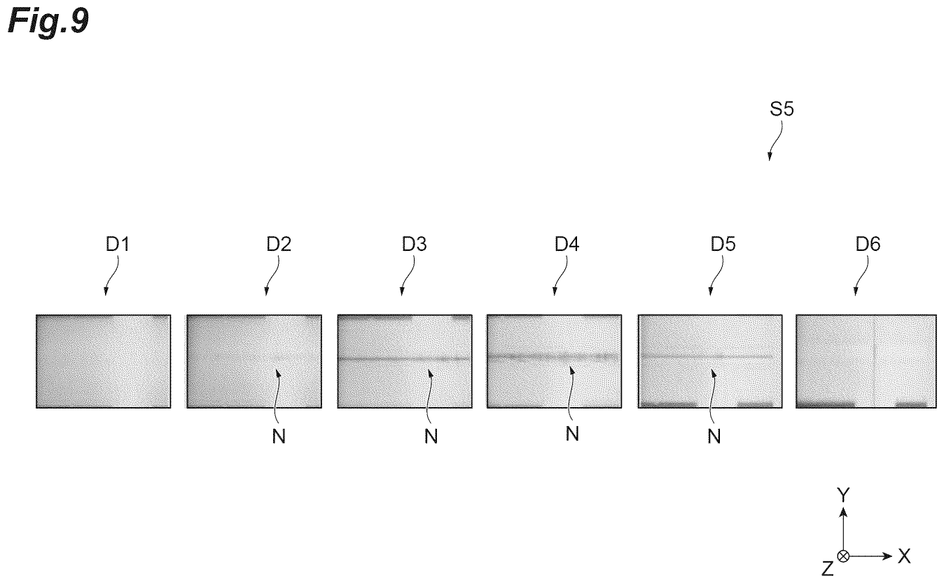

FIG. 9 is a view illustrating a plurality of the interface images. In FIG. 9, some interface images D1 to D6 are selected and illustrated among the plurality of interface images acquired as described above. The defocus values corresponding to the interface images D1 to D6 increase in order from the interface image D1 toward the interface image D6. As one example, the interface image D1 corresponds to a defocus value of 178 μm, the interface image D2 corresponds to a defocus value of 182 μm, the interface image D3 corresponds to a defocus value of 186 μm, the interface image D4 corresponds to a defocus value of 190 μm, the interface image D5 corresponds to a defocus value of 194 μm, and the interface image D6 corresponds to a defocus value of 198 μm. Here, an image N of damage caused by the laser light L1 is included in the interface images D2 to D5 among the interface images D1 to D6.

In such a manner, depending on the converging position (defocus value) of the laser light L1, the image N of damage caused by the laser light L1 may or may not appear in the interface images. Furthermore, when the converging position of the laser light L1 is within a range where the image N of damage appears in the interface image, the weakened regions J that allow the object 5 to be cut with good quality tend to be suitably formed. Here, as one example, it is considered that the defocus value at which the weakened regions J are suitably formed exists within a defocus value range of 182 μm to 194 μm, corresponding to the interface images D2 to D5.

Based on such finding, in step S5, subsequently, the control unit 30 acquires the range of the converging position of the first processing in the Z direction, in which the interface images D2 to D6 including the image N of damage caused by the laser light L1 are acquired among the plurality of acquired interface images, as one condition of the laser processing (third step). As one example, here, a defocus value range (namely, the range of the converging position) of 182 μm to 194 μm corresponding to the interface images D2 to D5 can be acquired. Incidentally, the control unit 30 may automatically perform a determination as to whether the image N of damage is included in a certain interface image, through image processing of the interface images.

Alternatively, the control unit 30 may cause the recording unit 35 to record each of the plurality of acquired interface images in association with each corresponding converging position of the first processing (third process), and may control the display unit 33 to display each of the interface images on the display unit 33, the interface images being recorded in the recording unit 35 (fourth process). Accordingly, a user may be prompted to perform a determination as to whether the image N of damage is included in a certain interface image, based on the interface images displayed on the display unit 33.

Meanwhile, the range of the converging position in which the weakened regions J are suitably formed in the functional element layer 52 is more easily obtained on a functional element layer 52 side than at the interface B between the substrate 51 and the functional element layer 52. In the above example, the defocus value DB at which the converging position is at the interface B is 178 μm, but by changing the defocus value within a range of 174 μm to 202 μm, the interface images D2 to D6 in which the image N of damage is included are obtained at 182 μm to 194 μm.

In such a manner, a position range in the Z direction (defocus value) in which the converging position is changed in step S5 can include a first range (for example, a defocus value range of 174 μm to 178 μm) located closer to the first surface 5a side than to the interface B, and a second range (for example, a defocus value range of 178 μm to 202 μm) located closer to a second surface 5b side than to the interface B and wider than the first range.

In the subsequent step, a more suitable value of one converging position is determined from the range of the converging position acquired in step S5 (step S6). For that purpose, in step S6, first, the object 5 in which the first processing is performed at a plurality of the converging positions in step S5 to form the weakened regions J is cut along each of the weakened regions J (fourth step). The weakened regions J are formed along each of a plurality of the lines A along the X direction. Therefore, here, the object 5 is cut along each of the plurality of lines A along the X direction.

A method for cutting the object 5 may be a method in which a modified region and a crack extending from the modified region are formed inside the object 5 by irradiating the object 5 with the laser light along each of the lines A, and cutting is performed starting from the modified region and the crack (laser dicing).

Thereafter, in step S6, an image of the front surface (second surface 5b) of the functional element layer 52 of the cut object 5 is captured (fourth step). Accordingly, a more suitable converging position can be determined by evaluating cutting quality corresponding to the first processing at each of the converging positions, based on the obtained image. Incidentally, when an image of the second surface 5b is captured, the third imaging unit constituted by the second focusing unit 27 and the third camera 29 may be used, or another imaging device may be used. As described above, processing conditions suitable for forming the weakened regions J are obtained.

As described above, in the processing condition acquisition method according to the present embodiment, conditions of the laser processing for forming the weakened regions J in the functional element layer 52 on the second surface 51b side of the substrate 51 are acquired by performing irradiation with the laser light L1 from the first surface 5a side of the substrate 51 of the object 5. For that purpose, laser processing (first processing) is performed a plurality of times while changing the converging position of the laser light L1 in the Z direction within a range including the interface B between the substrate 51 and the functional element layer 52. In addition, interface images are acquired by capturing images of the interface B between the substrate 51 and the functional element layer 52 at each of the positions where the laser processing is performed a plurality of times. Then, the range of the converging position of the laser light L1 in which the interface images including the image N of damage caused by the laser light L1 are acquired among a plurality of the interface images is acquired as one condition of the laser processing. In such a manner, according to this method, a suitable processing condition (the range of the converging position, in the above example, the range of the defocus value) when the weakened regions J are formed can be acquired.

In addition, in the processing condition acquisition method according to the present embodiment, the position range in the Z direction in which the converging position is changed in step S5 includes the first range located closer to the first surface 5a side than to the interface B, and the second range located closer to a side opposite to the first surface 5a (second surface 5b side) than to the interface B, and wider than the first range. In such a manner, the range where the converging position is changed is made wider on the functional element layer 52 side than at the interface B, so that the range can be quickly and reliably acquired.

In addition, in the processing condition acquisition method according to the present embodiment, in step S6, the object 5 is cut, and an image of the front surface of the functional element layer 52 of the cut object 5 is captured. In step S5, irradiation is performed with the laser light L1 along the X direction (line A) along the first surface 5a, and in step S6, the object 5 is cut along the X direction. In such a manner, by actually cutting the object 5 and capturing an image of the front surface of the functional element layer 52, a more suitable converging position can be determined through the evaluation of cutting quality.

In addition, in the processing condition acquisition method according to the present embodiment, in step S4, the second processing is performed as laser processing a plurality of times at different positions in the first surface 5a while changing the burst number of the laser light L1 that is pulsed light. In addition, in step S4, the first surface image is acquired by capturing an image of the first surface 5a at each of the positions (lines A) in the first surface 5a, the second processing being performed at the positions a plurality of times. Then, the burst number of the second processing at which the first surface images in which no damage occurs to the first surface 5a are acquired among a plurality of the acquired first surface images is acquired as another condition of the laser processing. For this reason, a suitable processing condition (burst number) which allows the weakened regions J to be formed such that no damage occurs to the first surface 5a that is an incident surface for the laser light L1 can be acquired.

Here, in the laser processing device 1 according to the present embodiment, conditions of the laser processing for forming the weakened regions J in the functional element layer 52 on the second surface 51b side of the substrate 51 are acquired by performing irradiation with the laser light L1 from the first surface 5a side of the substrate 51 of the object 5. For that purpose, the first processing that is laser processing is performed a plurality of times while changing the converging position of the laser light L1 in the Z direction within a range including the interface B between the substrate 51 and the functional element layer 52. In addition, the interface image is acquired by capturing an image of the interface B between the substrate 51 and the functional element layer 52 at each of the positions (lines A) where the first processing is performed a plurality of times. Then, in the laser processing device 1, each of a plurality of the interface images is recorded in the recording unit 35 in association with each corresponding converging position. Accordingly, by referring to the record, the range of the converging position in which the interface images including the image N of damage caused by the laser light L1 are acquired among the plurality of interface images can be acquired as one condition of the laser processing. In such a manner, according to the laser processing device 1, a suitable processing condition (the range of the converging position) for forming the weakened regions J can be acquired.

In addition, the laser processing device 1 according to the present embodiment includes the display unit 33 that displays images captured by the second imaging unit (second camera 25), and the control unit 30 may control the display unit 33 to display each of the interface images on the display unit 33, the interface images being recorded in the recording unit 35. In this case, the range of the converging position in which the interface images including the image N of damage caused by the laser light L are acquired among the plurality of interface images can be easily identified based on the interface images displayed on the display unit 33.

The embodiment has described one aspect of the present disclosure. Therefore, the present disclosure is not limited to the aspect, and can be arbitrarily modified.

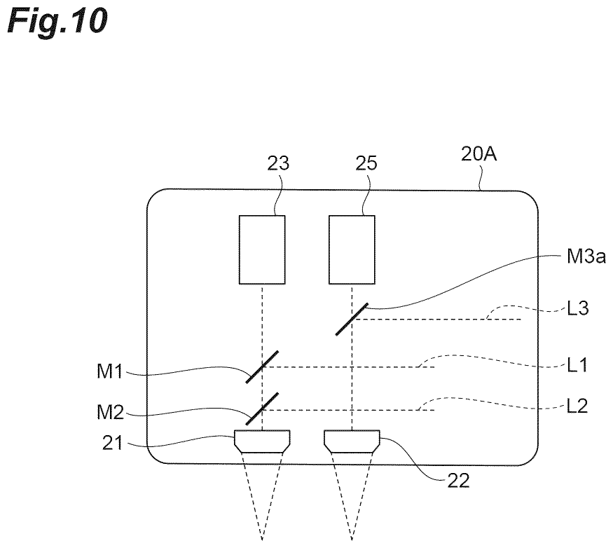

FIG. 10 is a schematic view illustrating a schematic configuration of a head unit according to a modification example. A head unit 20A illustrated in FIG. 10 differs from the head unit 20 in that the optical axes of the laser light L1 and the first observation light L2 and the optical axis of the transmissive light L3 are separate axes. Therefore, the head unit 20A further includes a third focusing unit 22 that focuses the transmissive light L3 toward the object 5, in addition to the first focusing unit 21 that focuses the laser light L1 and the first observation light L2 toward the object 5. In such a manner, whether the laser light L1, the first observation light L2, and the transmissive light L3 are set to have a coaxial axis or to have separate axes can be arbitrarily selected.

In addition, the laser processing device 1 illustrated in FIG. 1 is an example of the case where the table 10 that is transparent and that is transmissive to the second observation light L4 such as visible light and near-infrared light can be used. However, in the laser processing device 1, it is not essential to use the table 10 that is transparent. When the object 5 is supported by an opaque table (for example, a normal porous table), the third imaging unit constituted by the second focusing unit 27 and the third camera 29 may be disposed on the same side as the head unit 20 with respect to the table. In this case, when an image of the functional element layer 52 of the object 5 is captured by the third imaging unit, the object 5 may be resupported such that the functional element layer 52 faces the third imaging unit.

Further, in the above example, an example in which in each of step S4 of acquiring the burst number as a processing condition and step S5 of acquiring the range of the converging position, processing is performed along one line A for one burst number and one converging position has been described; however, processing may be performed at different positions on one line A for two or more burst numbers and two or more converging positions. The reason is that it is considered that processing a length of approximately 15 mm is sufficient to determine the presence or absence of the images M and N of damage when a suitable burst number and converging position are evaluated.

Incidentally, after laser processing in which the laser light L1 is incident on the object 5 from the first surface 5a side to form the weakened region J on the functional element layer 52 side as desired above, third processing in which a modified region and a crack extending from the modified region are formed in the substrate 51 by performing irradiation with the laser light, and fourth processing in which the substrate 51 is ground from the first surface 5a side to be thinned to a desired thickness may be further performed. In the third processing, the converging position of the laser light is moved relatively along the line A while causing the laser light to be incident on the object 5 from the first surface 5a side, so that a modified region can be formed inside the substrate 51 at the converging position and a crack extending from the modified region in the Z direction can be formed.

### INDUSTRIAL APPLICABILITY

The processing condition acquisition method and the laser processing device capable of acquiring processing conditions suitable for forming the weakened region are provided.

### REFERENCE SIGNS LIST

1: laser processing device, 5: object, 5a: first surface, 10: table (support unit), 20: head unit (laser irradiation unit, imaging unit), 30: control unit, 33: display unit, 35: recording unit, 51: substrate, 51b: second surface, 52: functional element layer, L1: laser light, L3: transmissive light, J: weakened region.

1. A processing condition acquisition method for acquiring conditions of laser processing for forming a weakened region in a functional element layer by irradiating an object with laser light from a first surface side, the object including a substrate including the first surface and a second surface opposite to the first surface, and the functional element layer provided on the second surface of the substrate, the method comprising:
a first step of performing first processing as the laser processing in a plurality of times at different positions in the first surface while changing a converging position of the laser light in a Z direction intersecting the first surface within a range including an interface between the substrate and the functional element layer;
a second step of acquiring an interface image by capturing an image of the interface between the substrate and the functional element layer from the first surface side at each of the positions in the first surface in which the first processing is performed in plurality of times using transmissive light transmitting through the substrate; and
a third step of acquiring a range of the converging position of the first processing in the Z direction, in which the interface image including damage caused by the laser light is acquired among a plurality of the interface images acquired in the second step, as one condition of the laser processing.

2. The processing condition acquisition method according to claim 1,
wherein a position range in the Z direction in which the converging position is changed in the first step includes a first range located closer to the first surface side than to the interface, and a second range located closer to a side opposite to the first surface than to the interface, and wider than the first range.

3. The processing condition acquisition method according to claim 1, further comprising:
a fourth step of cutting the object and capturing an image of a front surface of the functional element layer of the cut object after the first step, the second step, and the third step,
wherein in the first step, irradiation is performed with the laser light along an X direction along the first surface, and
in the fourth step, the object is cut along the X direction.

4. The processing condition acquisition method according to claim 1, further comprising:
a fifth step of performing second processing as the laser processing in a plurality of times at different positions in the first surface while changing a burst number of the laser light that is pulsed light;
a sixth step of acquiring a first surface image by capturing an image of the first surface at each of the positions in the first surface in which the second processing is performed in a plurality of times; and
a seventh step of acquiring the burst number of the second processing, at which the first surface image in which no damage occurs to the first surface is acquired among a plurality of the first surface images acquired in the sixth step, as another condition of the laser processing.

5. A laser processing device that acquires conditions of laser processing for forming a weakened region in a functional element layer by irradiating an object with laser light from a first surface side, the object including a substrate including the first surface and a second surface opposite to the first surface, and the functional element layer provided on the second surface of the substrate, the device comprising:
a support unit configured to support the object;
a laser irradiation unit configured to irradiate the object supported by the support unit with the laser light from the first surface side;
an imaging unit configured to capture an image of the object supported by the support unit from the first surface side using transmissive light transmitting through the substrate; and
a control unit configured to control the laser irradiation unit and the imaging unit,
wherein the control unit executes a first process of controlling the laser irradiation unit to perform first processing as the laser processing in a plurality of times at different positions in the first surface while changing a converging position of the laser light in a Z direction intersecting the first surface within a range including an interface between the substrate and the functional element layer,
a second process of controlling the imaging unit to capture an image of the interface between the substrate and the functional element layer from the first surface side at each of the different positions in the first surface in which the first processing is performed in a plurality of times using the transmissive light, thereby acquiring an interface image, and
a third process of recording each of a plurality of the interface images acquired in the second process, in association with each of the corresponding converging position of the first processing.

6. The laser processing device according to claim 5, further comprising:
a display unit configured to display the image captured by the imaging unit,
wherein the control unit executes a fourth process of controlling the display unit to display each of the interface images recorded in the third process on the display unit.
